(19) United States
(12) Patent Application Publication
(10) Pub. No.: US 2026/0045451 A1
(43) Pub. Date: Feb. 12, 2026

(54) MATCHING NETWORK ADJUSTMENT IN ANTICIPATION OF SEMICONDUCTOR MANUFACTURING PROCESS STEPS

(71) Applicant: ASM IP Holding B.V., Almere (NL)

(72) Inventors: Imran Ahmed Bhutta, Moorestown, NJ (US); Tomislav Lozic, Gilbert, AZ (US)

(21) Appl. No.: 19/294,626

(22) Filed: Aug. 8, 2025

Related U.S. Application Data
(60) Provisional application No. 63/681,478, filed on Aug. 9, 2024.

(51) Int. Cl. H01J 37/32; H01L 21/02

(52) U.S. Cl. CPC H01J 37/32183; H01J 37/32935; H01J 2237/332; H01L 21/02274

(57) ABSTRACT

In one embodiment, a system for controlling a matching network of a semiconductor manufacturing system is disclosed. The matching network comprises an electronically variable reactance element (EVRE) that varies its total reactance using different match configurations. A plasma chamber carries out a process upon a substrate, the process comprising process steps including at least a first process step and a second process step. A memory, for each process step, stores instructions for carrying out the process step. A control circuit, while continuously carrying out each of the process steps of the process, upon anticipation that the plasma chamber will be transitioning from the first process step to the second process step, alters the match configuration to a new match configuration based on the instructions for carrying out the second process step.

### CROSS-REFERENCE TO RELATED APPLICATIONS

This application claims priority to U.S. Provisional Patent Application Ser. No. 63/681,478 filed Aug. 9, 2024 titled MATCHING NETWORK ADJUSTMENT IN ANTICIPATION OF SEMICONDUCTOR MANUFACTURING PROCESS STEPS, the disclosure of which is hereby incorporated by reference in its entirety.

### BACKGROUND

The semiconductor device fabrication process uses plasma processing at different stages of fabrication to make a semiconductor device, such as a microprocessor, a memory chip, or another integrated circuit or device. Plasma processing involves energizing a gas mixture by imparting energy to the gas molecules by the introduction of RF (radio frequency) energy into the gas mixture. This gas mixture is typically contained in a vacuum chamber, also called a plasma chamber, and the RF energy is introduced through electrodes or other means in the chamber. In a typical plasma process, the RF source generates power at the desired RF frequency and power, and this power is transmitted through the RF cables and networks to the plasma chamber.

To provide efficient transfer of power from the RF source to the plasma chamber, a matching network is positioned between the RF source and the plasma chamber. The purpose of the matching network is to transform the plasma impedance to a value suitable for the RF source. In many cases, particularly in the semiconductor fabrication processes, the RF power is transmitted through 50 Ohm coaxial cables and the system impedance (output impedance) of the RF source is also 50 Ohm. On the other hand, the impedance of the plasma, driven by the RF power, varies. The impedance on the input side of the matching network must be transformed to non-reactive 50 Ohm (i.e., 50+j0) for maximum power transmission. matching network perform this task of continuously transforming the plasma impedance to 50 Ohm for the RF source.

In typical matching networks for semiconductor manufacturing processes, match configurations and tuning parameters are set at the beginning of a process. As processes become more complex with different steps of the process using different power levels and varying gas chemistries, however, matching requirements change for the different steps of a process. Typical matching networks using electro-mechanical components, such as vacuum variable capacitors (VVCs), that cannot vary match configurations mid-process (such as between the steps of a process) due to the slow switching speed of the mechanical components. For such matching networks, the time required to move to a new match configuration is dependent upon the speed of the mechanical element's physical movement, which may take hundreds of milliseconds to several seconds to move from one position to another. Such slow changing of match configurations mid-process could disrupt the plasma and the overall semiconductor manufacturing process. Where transitioning to a new process step involves a significant change in the power being provided by the RF source, additional steps may be added to the process to prevent sudden changes to power that could not be handled by the electro-mechanical matching network, but such a solution will slow down the overall process.

### BRIEF SUMMARY

The present disclosure is directed to utilizing solid-state matching networks that can change positions in sub-millisecond time to enable the changing of match configurations mid-process in anticipation of a new process step without disrupting the process being undertaken by the semiconductor manufacturing system. By enabling matching configuration changes for different process steps, the parameters of the matching network can be optimized for each process, rather than a one-size-fits-all set of parameters that merely allow all the process steps to run. Such an approach avoids disrupting the plasma or the overall semiconductor manufacturing process. Changing match configurations in advance of changing process steps enables shortened tune time, and thus more efficient power transfer. The disclosure provides a particular advantage when transitioning to a new process step involves a significant change in the power being provided by the RF source. The speed of the solid state matching network (for example, a matching network utilizing electronically variable capacitors) enables a rapid adjustment to the changed power, thus ensuring efficient power transfer without disrupting the plasma.

In one aspect, the present disclosure may be directed to a system for controlling a matching network of a semiconductor manufacturing system, the system comprising a matching network configured to provide RF power from an RF source to a plasma chamber; wherein the matching network comprises an electronically variable reactance element (EVRE) configured to provide a variable total reactance, the EVRE comprising discrete reactance elements configured to switch in and out of the matching network to vary the total reactance provided by the EVRE and thereby enable the matching network to provide different match configurations; wherein the plasma chamber is configured to carry out a process upon a substrate, the process comprising process steps including at least a first process step and a second process step; a memory configured, for each process step, to store instructions for carrying out the process step; and a control circuit configured to, while continuously carrying out each of the process steps of the process, upon anticipation that the plasma chamber will be transitioning from the first process step to the second process step, alter the match configuration to a new match configuration based on the instructions for carrying out the second process step.

In another aspect, a method of controlling a matching network of a semiconductor manufacturing system is disclosed. The method comprises providing, by a matching network, RF power from an RF source to a plasma chamber; wherein the matching network comprises an electronically variable reactance element (EVRE) configured to provide a variable total reactance, the EVRE comprising discrete reactance elements configured to switch in and out of the matching network to vary the total reactance provided by the EVRE and thereby enable the matching network to provide different match configurations; wherein the plasma chamber is configured to carry out a process upon a substrate, the process comprising process steps including at least a first process step and a second process step; for each process step, storing instructions for carrying out the process step; and while continuously carrying out each of the process steps of the process, upon anticipation that the plasma chamber will be transitioning from the first process step to the second process step, altering the match configuration to a new match configuration based on the instructions for carrying out the second process step.

### BRIEF DESCRIPTION OF THE DRAWINGS

The present disclosure will become more fully understood from the detailed description and the accompanying drawings, wherein:

FIG. 1 is a block diagram of an embodiment of a semiconductor processing system, including a system for controlling a matching network of the semiconductor processing system;

FIG. 2 is a block diagram of an embodiment of a semiconductor processing system having an L-configuration matching network;

FIG. 3 is a block diagram of an embodiment of a semiconductor processing system having a pi-configuration matching network;

FIG. 4 is a block diagram of an embodiment of an electronic circuit for providing a variable capacitance using an electronically variable capacitor having two capacitor arrays;

FIG. 5 is a block diagram of an embodiment of a variable capacitance system for switching in and out discrete capacitors of an electronically variable capacitor;

FIG. 6 is a flow chart showing an embodiment of a process for matching an impedance by altering a variable capacitance;

FIG. 7 is a flow chart for a method of controlling a matching network of a semiconductor manufacturing system; and

FIGS. 8A and 8B provide graphs comparing the speed of a Plasma Enhanced Atomic Layer Deposition (PEALD) semiconductor process with and without the disclosed system for controlling a matching network of the semiconductor processing system.

### DETAILED DESCRIPTION

The following description of the preferred embodiment(s) is merely exemplary in nature and is in no way intended to limit the invention or inventions. The description of illustrative embodiments is intended to be read in connection with the accompanying drawings, which are to be considered part of the entire written description. In the description of the exemplary embodiments disclosed herein, any reference to direction or orientation is merely intended for convenience of description and is not intended in any way to limit the scope of the present inventions. The discussion herein describes and illustrates some possible non-limiting combinations of features that may exist alone or in other combinations of features. Furthermore, as used herein, the term “or” is to be interpreted as a logical operator that results in true whenever one or more of its operands are true. Furthermore, as used herein, the phrase “based on” is to be interpreted as meaning “based at least in part on,” and therefore is not limited to an interpretation of “based entirely on.”

Features of the present inventions may be implemented in software, hardware, firmware, or combinations thereof. The computer programs described herein are not limited to any particular embodiment, and may be implemented in an operating system, application program, foreground or background processes, driver, or any combination thereof. The computer programs may be executed on a single computer or server processor or multiple computer or server processors.

Processors described herein may be any central processing unit (CPU), microprocessor, micro-controller, computational, or programmable device or circuit configured for executing computer program instructions (e.g., code). Various processors may be embodied in computer and/or server hardware of any suitable type (e.g., desktop, laptop, notebook, tablets, cellular phones, etc.) and may include all the usual ancillary components necessary to form a functional data processing device including without limitation a bus, software and data storage such as volatile and non-volatile memory, input/output devices, graphical user interfaces (GUIs), removable data storage, and wired and/or wireless communication interface devices including Wi-Fi, Bluetooth, LAN, etc.

Computer-executable instructions or programs (e.g., software or code) and data described herein may be programmed into and tangibly embodied in a non-transitory computer-readable medium that is accessible to and retrievable by a respective processor as described herein which configures and directs the processor to perform the desired functions and processes by executing the instructions encoded in the medium. A device embodying a programmable processor configured to such non-transitory computer-executable instructions or programs may be referred to as a “programmable device”, or “device”, and multiple programmable devices in mutual communication may be referred to as a “programmable system.” It should be noted that non-transitory “computer-readable medium” as described herein may include, without limitation, any suitable volatile or non-volatile memory including random access memory (RAM) and various types thereof, read-only memory (ROM) and various types thereof, USB flash memory, and magnetic or optical data storage devices (e.g., internal/external hard disks, floppy discs, magnetic tape CD-ROM, DVD-ROM, optical disk, ZIP™ drive, Blu-ray disk, and others), which may be written to and/or read by a processor operably connected to the medium.

In certain embodiments, the present invention may be embodied in the form of computer-implemented processes and apparatuses such as processor-based data processing and communication systems or computer systems for practicing those processes. The present invention may also be embodied in the form of software or computer program code embodied in a non-transitory computer-readable storage medium, which when loaded into and executed by the data processing and communications systems or computer systems, the computer program code segments configure the processor to create specific logic circuits configured for implementing the processes.

As used throughout, ranges are used as shorthand for describing each and every value that is within the range. Any value within the range can be selected as the terminus of the range. In addition, all references cited herein are hereby incorporated by referenced in their entireties. In the event of a conflict in a definition in the present disclosure and that of a cited reference, the present disclosure controls.

In the following description, where circuits are shown and described, one of skill in the art will recognize that, for the sake of clarity, not all peripheral circuits or components are shown in the figures or described in the description. Further, the terms “couple” and “operably couple” can refer to a direct or indirect coupling of two components of a circuit.

The following description of the preferred embodiment(s) is merely exemplary in nature and is in no way intended to limit the invention or inventions. The description of illustrative embodiments is intended to be read in connection with the accompanying drawings, which are to be considered part of the entire written description. In the description of the exemplary embodiments disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “left,” “right,” “top,” “bottom,” “front” and “rear” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” “secured” and other similar terms refer to a relationship wherein structures are secured or attached to one another either directly or indirectly through intervening structures, as well as both movable or rigid attachments or relationships, unless expressly described otherwise. The discussion herein describes and illustrates some possible non-limiting combinations of features that may exist alone or in other combinations of features. Furthermore, as used herein, the term “or” is to be interpreted as a logical operator that results in true whenever one or more of its operands are true. Furthermore, as used herein, the phrase “based on” is to be interpreted as meaning “based at least in part on,” and therefore is not limited to an interpretation of “based entirely on.”

As used throughout, ranges are used as shorthand for describing each and every value that is within the range. Any value within the range can be selected as the terminus of the range. In addition, all references cited herein are hereby incorporated by referenced in their entireties. In the event of a conflict in a definition in the present disclosure and that of a cited reference, the present disclosure controls.

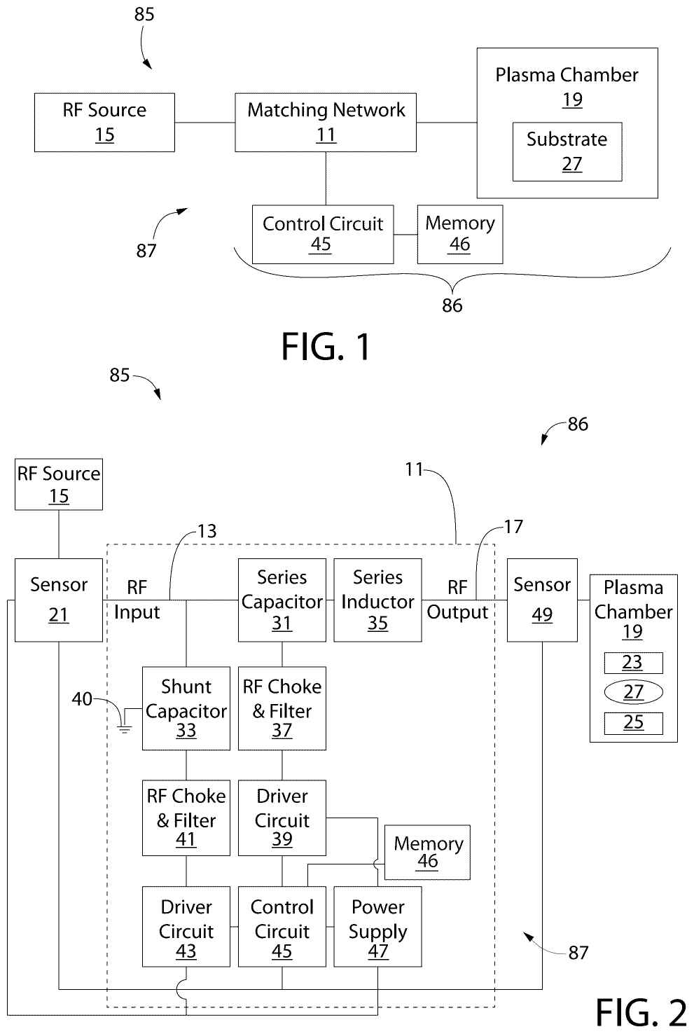

Referring to FIG. 1, a semiconductor device processing system 85 utilizing an RF source 15 is shown. The system 85 includes an RF source 15 and a semiconductor processing tool 86. The semiconductor processing tool 86 includes a matching network 11 and a plasma chamber 19. In other embodiments, the RF source 15 or other power source can form part of the semiconductor processing tool. For the semiconductor processing systems and their components (e.g., matching networks, EVCs, and EVREs) discussed herein, applicant incorporates by reference in its entirety U.S. Pub. No. 2024/0177970.

The semiconductor device can be a microprocessor, a memory chip, or other type of integrated circuit or device. A substrate 27 can be placed in the plasma chamber 19, where the plasma chamber 19 is configured to deposit a material layer onto the substrate 27 or etch a material layer from the substrate 27. Plasma processing involves energizing a gas mixture by imparting energy to the gas molecules by introducing RF energy into the gas mixture. This gas mixture is typically contained in a vacuum chamber (the plasma chamber 19), and the RF energy is typically introduced into the plasma chamber 19 through electrodes. Thus, the plasma can be energized by coupling RF power from an RF source 15 into the plasma chamber 19 to perform deposition or etching.

In a typical plasma process, the RF source 15 generates power at a radio frequency—which is typically within the range of 3 kHz and 300 GHz—and this power is transmitted through RF cables and networks to the plasma chamber 19. In order to provide efficient transfer of power from the RF source 15 to the plasma chamber 19, an intermediary circuit is used to match the fixed impedance of the RF source 15 with the variable impedance of the plasma chamber 19. Such an intermediary circuit is commonly referred to as an RF impedance matching network, or more simply as a matching network. The purpose of the matching network 11 is to transform the variable plasma impedance to a value that more closely matches the fixed impedance of the RF source 15. Commonly owned U.S. patent application Ser. No. 14/669,568, the disclosure of which is incorporated herein by reference in its entirety, provides an example of such a matching network.

### Matching Network

FIG. 2 is a block diagram of an embodiment of a semiconductor processing system 85 having a semiconductor processing tool 86 that includes an L-configuration matching network 11. The matching network 11 has an RF input 13 connected to an RF source 15 and an RF output 17 connected to a plasma chamber 19. An RF input sensor 21 can be connected between the matching network 11 and the RF source 15. An RF output sensor 49 can be connected between the matching network 11 and the plasma chamber 19 so that the RF output from the impedance matching network, and the plasma impedance presented by the plasma chamber 19, may be monitored. Certain embodiments may include only one of the input sensor 21 and the output sensor 49. The functioning of these sensors 21, 49 are described in greater detail below.

As discussed above, the matching network 11 serves to help maximize the amount of RF power transferred from the RF source 15 to the plasma chamber 19 by matching the impedance at the RF input 13 to the fixed impedance of the RF source 15. The matching network 11 can consist of a single module within a single housing designed for electrical connection to the RF source 15 and plasma chamber 19. In other embodiments, the components of the matching network 11 can be located in different housings, some components can be outside of the housing, and/or some components can share a housing with a component outside the matching network.

The plasma within the plasma chamber 19 typically undergoes certain fluctuations outside of operational control so that the impedance presented by the plasma chamber 19 is a variable impedance. Since the variable impedance of the plasma chamber 19 cannot be fully controlled, an impedance matching network may be used to create an impedance match between the plasma chamber 19 and the RF source 15. Moreover, the impedance of the RF source 15 may be fixed at a set value by the design of the particular RF source 15. Although the fixed impedance of the RF source 15 may undergo minor fluctuations during use, due to, for example, temperature or other environmental variations, the impedance of the RF source 15 is still considered a fixed impedance for purposes of impedance matching because the fluctuations do not significantly vary the fixed impedance from the originally set impedance value. Other types of RF source 15 may be designed so that the impedance of the RF source 15 may be set at the time of, or during, use. The impedance of such types of RF sources 15 is still considered fixed because it may be controlled by a user (or at least controlled by a programmable controller) and the set value of the impedance may be known at any time during operation, thus making the set value effectively a fixed impedance.

The RF source 15 may comprise an RF generator configured to generate an RF signal at an appropriate frequency and power for the process performed within the plasma chamber 19. The RF source 15 may be electrically connected to the RF input 13 of the matching network 11 using a coaxial cable, which for impedance matching purposes would have the same fixed impedance as the RF source 15.

The plasma chamber 19 includes a first electrode 23 and a second electrode 25, and in processes that are well known in the art, the first and second electrodes 23, 25, in conjunction with appropriate control systems (not shown) and the plasma in the plasma chamber 19, enable one or both of deposition of materials onto a substrate 27 and etching of materials from the substrate 27.

In the exemplified embodiment, the matching network 11 includes a series variable capacitor 31, a shunt variable capacitor 33, and a series inductor 35 to form an ‘L’ type matching network. The shunt variable capacitor 33 is shown shunting to a reference potential, which in this embodiment is ground 40.

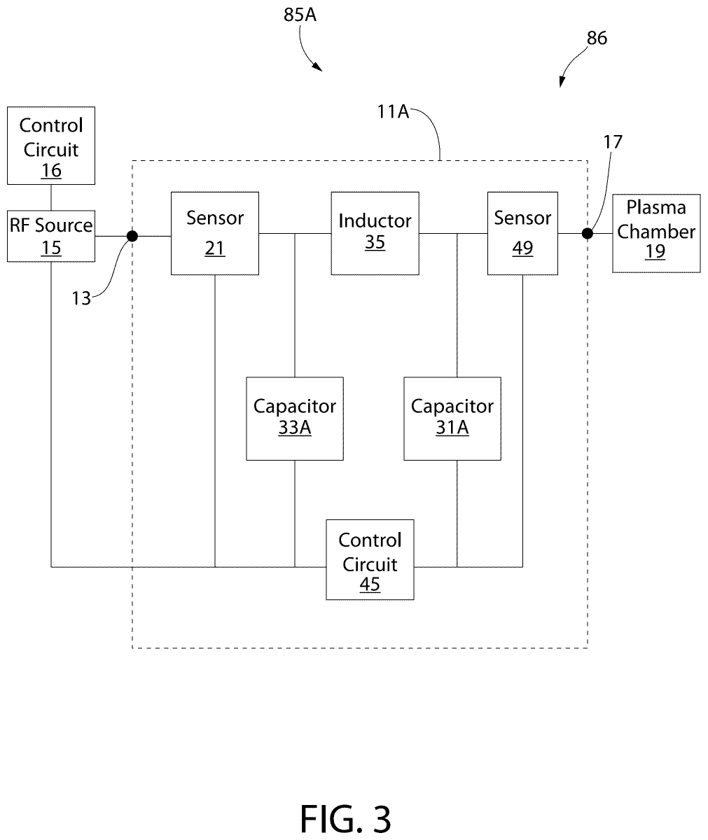

Alternatively, the matching network 11 may be configured in other matching network configurations, such as a ‘T’ type configuration or a ‘[ ]’ or ‘pi’ type configuration, as will be shown in FIG. 3. In certain embodiments, the variable capacitors and the switching circuit described below may be included in any configuration appropriate for a matching network.

In the exemplified embodiment, and referring to FIG. 2, each of the series variable capacitor 31 and the shunt variable capacitor 33 may be an electronic variable capacitor (EVC), as described in U.S. Pat. No. 7,251,121, the EVC being effectively formed as a capacitor array formed by a plurality of discrete capacitors. The series variable capacitor 31 is coupled in series between the RF input 13 and the RF output 17 (which is also in parallel between the RF source 15 and the plasma chamber 19). The shunt variable capacitor 33 is coupled between the RF input 13 and ground 40. In other configurations, the shunt variable capacitor 33 may be coupled in parallel between the RF output 19 and ground 40. Other configurations may also be implemented without departing from the functionality of a matching network. In still other configurations, the shunt variable capacitor 33 may be coupled in parallel between a reference potential and one of the RF input 13 and the RF output 19.

The series variable capacitor 31 is connected to a series RF choke and filter circuit 37 and to a series driver circuit 39. Similarly, the shunt variable capacitor 33 is connected to a shunt RF choke and filter circuit 41 and to a shunt driver circuit 43. Each of the series and shunt driver circuits 39, 43 are connected to a control circuit 45, which is configured with an appropriate processor and/or signal generating circuitry to provide an input signal for controlling the series and shunt driver circuits 39, 43. A power supply 47 is connected to each of the RF input sensor 21, the series driver circuit 39, the shunt driver circuit 43, and the control circuit 45 to provide operational power, at the designed currents and voltages, to each of these components. The voltage levels provided by the power supply 47, and thus the voltage levels employed by each of the RF input sensor 21, the series driver circuit 39, the shunt driver circuit 43, and the control circuit 45 to perform the respective designated tasks, is a matter of design choice. In other embodiments, a variety of electronic components can be used to enable the control circuit 45 to send instructions to the variable capacitors. Further, while the driver circuit 39, 43 and RF choke and filter 37, 41 are shown as separate from the control circuit 45, these components can also be considered as forming part of the control circuit 45. The control circuit 45 may include or be coupled to a memory 46. The memory 46 may store instructions for the control circuit 45 as well as other data that the control circuit 45 may utilize.

In the exemplified embodiment, the control circuit 45 includes a processor. The processor may be any type of properly programmed processing device, such as a computer or microprocessor, configured for executing computer program instructions (e.g., code). The processor may be embodied in computer and/or server hardware of any suitable type (e.g., desktop, laptop, notebook, tablets, cellular phones, etc.) and may include all the usual ancillary components necessary to form a functional data processing device including without limitation a bus, software and data storage (such as volatile and non-volatile memory), input/output devices, graphical user interfaces (GUIs), removable data storage, and wired and/or wireless communication interface devices including Wi-Fi, Bluetooth, LAN, etc. The processor of the exemplified embodiment is configured with specific algorithms to enable the matching network 11 to perform the functions described herein.

With the combination of the series variable capacitor 31 and the shunt variable capacitor 33, the combined impedances of the matching network 11 and the plasma chamber 19 may be controlled, using the control circuit 45, the series driver circuit 39, the shunt driver circuit 43, to match, or at least to substantially match, the fixed impedance of the RF source 15.

The control circuit 45 operates the matching network 11, as it receives multiple inputs, from sources such as the RF input sensor 21 and the series and shunt variable capacitors 31, 33, makes the calculations necessary to determine changes to the series and shunt variable capacitors 31, 33, and delivers commands to the series and shunt variable capacitors 31, 33 to create the impedance match. The control circuit 45 is of the type of control circuit that is commonly used in semiconductor fabrication processes, and therefore known to those of skill in the art. Any differences in the control circuit 45, as compared to control circuits of the prior art, arise in programming differences to account for the speeds at which the matching network 11 is able to perform switching of the variable capacitors 31, 33 and impedance matching.

Each of the series and shunt RF choke and filter circuits 37, 41 are configured so that DC signals may pass between the series and shunt driver circuits 39, 43 and the respective series and shunt variable capacitors 31, 33, while at the same time, the RF signal from the RF source 15 is blocked to prevent the RF signal from leaking into the outputs of the series and shunt driver circuits 39, 43 and the output of the control circuit 45. The series and shunt RF choke and filter circuits 37, 41 are of a type known to those of skill in the art.

FIG. 3 is a block diagram of an embodiment of a semiconductor processing system 85A having a pi-configuration matching network 11A, as opposed to the L-configuration matching network of FIG. 2. For case of understanding, this figure omits the RF chokes and filters, driver circuits, and power supplies of FIG. 2. Where FIG. 3 uses reference numbers identical to those of FIG. 2, it is understood that the relevant components can have features similar to those discussed with regard to FIG. 2.

The most significant difference between the L- and pi-configuration is that the L-configuration utilizes a series capacitor 31 and shunt capacitor 33, while the pi-configuration utilizes two shunt capacitors 31A, 33A. Nevertheless, the control circuit 45 can alter the capacitance of these shunt variable capacitors 31A, 33A to cause an impedance match. Each of these shunt variable capacitors 31A, 33A can be an EVC, as discussed above. They can be controlled by a choke, filter, and driver similar to the methods discussed above with respect to FIG. 2.

### EVC Capacitor Arrays

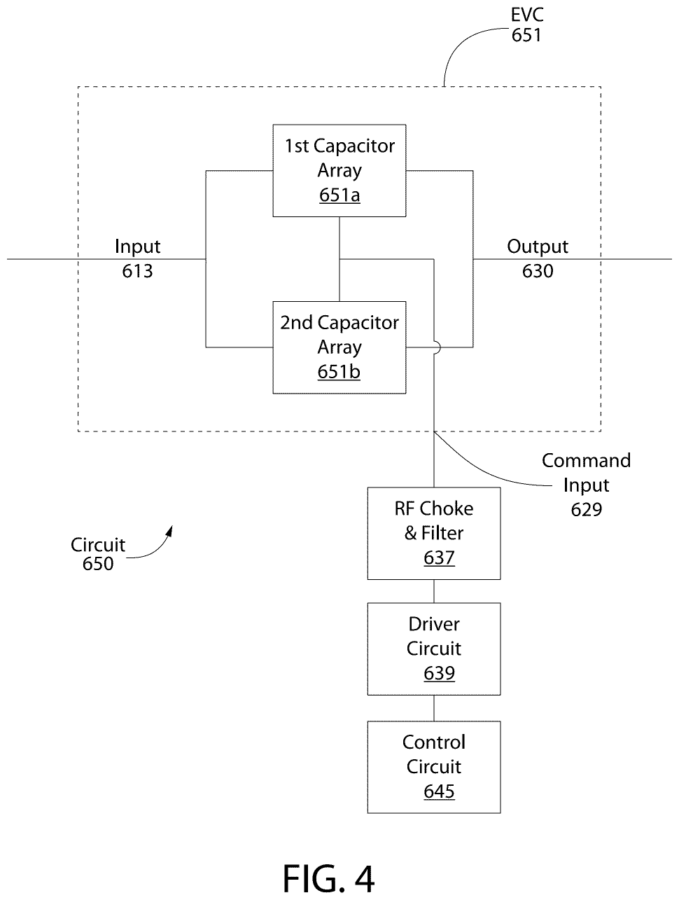

FIG. 4 shows an electronic circuit 650 for providing a variable capacitance according to one embodiment. The circuit 650 utilizes an EVC 651 that includes two capacitor arrays 651a, 651b. The first capacitor array 651a may comprise a plurality of first plurality of discrete capacitors, each having a first capacitance value. The second capacitor array 651b may comprise a plurality of second plurality of discrete capacitors, each having a second capacitance value. The first capacitance value is different from the second capacitance value, such that the EVC 651 can provide coarse and fine control of the capacitance produced by the EVC 651. The first capacitor array 651a and the second capacitor array 651b are coupled in parallel between a signal input 613 and a signal output 630.

The first and second capacitance values can be any values sufficient to provide the desired overall capacitance values for the EVC 651. In one embodiment, the second capacitance value is less than or equal to one-half (½) of the first capacitance value. In another embodiment, the second capacitance value is less than or equal to one-third (⅓) of the first capacitance value. In yet another embodiment, the second capacitance value is less than or equal to one-fourth (¼) of the first capacitance value.

The electronic circuit 650 further includes a control circuit 645, which can have features similar to control circuit 45 discussed above. The control circuit 645 is operably coupled to the first capacitor array 651a and to the second capacitor array 651b by a command input 629, the command input 629 being operably coupled to the first capacitor array 651a and to the second capacitor array 651b. In the exemplified embodiment, the command input 629 has a direct electrical connection to the capacitor arrays 651a, 651b, though in other embodiments this connection can be indirect. The coupling of the control circuit 645 to the capacitor arrays 651a, 651b will be discussed in further detail below.

The control circuit 645 is configured to alter the variable capacitance of the EVC 651 by controlling on and off states of (a) each discrete capacitor of the first plurality of discrete capacitors 651a and (b) each discrete capacitor of the second plurality of discrete capacitors 651b. As stated above, the control circuit 645 can have features similar to those described with respect to control circuit 45 of FIGS. 2-3. For example, the control circuit 645 can receive inputs from the capacitor arrays 651a, 651b, make calculations to determine changes to the capacitor arrays 651a, 651b, and delivers commands to the capacitor arrays 651a, 651b for altering the capacitance of the EVC 651. EVC 651 of FIG. 4 can include a plurality of electronic switches. Each electronic switch can be configured to activate and deactivate one or more discrete capacitors.

As with the control circuit 45 of FIGS. 2-3, the control circuit 645 can also be connected to a driver circuit 639 and an RF choke and filter circuit 637. The control circuit 645, driver circuit 639, and RF choke and filter circuit 637 can have capabilities similar to those discussed with regard to FIGS. 2-3. In the exemplified embodiment, the driver circuit 639 is operatively coupled between the control circuit 645 and the first and second capacitor arrays 651a, 651b. The driver circuit 639 is configured to alter the variable capacitance based upon a control signal received from the control circuit 645. The RF filter 637 is operatively coupled between the driver circuit 639 and the first and second capacitor arrays 651a, 651b. In response to the control signal sent by the control unit 645, the driver circuit 639 and RF filter 637 are configured to send a command signal to the command input 629. The command signal is configured to alter the variable capacitance by instructing at least one of the electronic switches to activate or deactivate (a) at least one the discrete capacitors of the first plurality of discrete capacitors or (b) at least one of the discrete capacitors of the second plurality of discrete capacitors.

In the exemplified embodiment, the driver circuit 639 is configured to switch a high voltage source on or off in less than 15 usec, the high voltage source controlling the electronic switches of each of the first and second capacitor arrays for purposes of altering the variable capacitance. The EVC 651, however, can be switched by any of the means or speeds discussed in the present application.

The control circuit 645 can be configured to calculate coarse and fine capacitance values to be provided by the respective capacitor arrays 651a, 651b. In the exemplified embodiment, the control circuit 645 is configured to calculate a coarse capacitance value to be provided by controlling the on and off states of the first capacitor array 651a. Further, the control circuit is configured to calculate a fine capacitance value to be provided by controlling the on and off states of the second capacitor array 651b. In other embodiments, the capacitor arrays 651a, 651b can provide alternative levels of capacitance. In other embodiments, the EVC can utilize additional capacitor arrays.

EVC 651 of FIG. 4 can be used in most systems requiring a varying capacitance. For example, EVC 651 can be used as the series EVC and/or shunt EVC in matching network 11 of FIG. 2, or as one or both of the shunt EVCs in matching network 11A of FIG. 3. It is often desired that the differences between the capacitance values allow for both a sufficiently fine resolution of the overall capacitance of the circuit and a wide range of capacitance values to enable a better impedance match at the input of a matching network, and EVC 651 allows this.

EVC 651 can also be used in a system or method for fabricating a semiconductor, a method for controlling a variable capacitance, and/or a method of controlling a matching network. Such methods can include altering at least one of the series variable capacitance and the shunt variable capacitance to the determined series capacitance value and the shunt capacitance value, respectively. This altering can be accomplishing by controlling, for each of the series EVC and the shunt EVC, on and off states of each discrete capacitor of each plurality of discrete capacitors. In other embodiments, EVC 651 and circuit 650 can be used in other methods and systems to provide a variable capacitance.

### Switching in and Out Discrete Capacitors to Vary EVC Capacitance

As discussed above, an EVC is a type of variable capacitor that can use multiple switches, each used to create an open or short circuit, with individual series capacitors to change the capacitance of the variable capacitor. The switches can be mechanical (such as relays) or solid state (such as PIN diodes, transistors, or other switching devices). The following is a discussion of methods for setting up an EVC or other variable capacitor to provide varying capacitances.

In what is sometimes referred to as an “accumulative setup” of an EVC or other variable capacitor, the approach to linearly increase the capacitor value from the minimum starting point (where all switches are open) is to incrementally increase the number of fine tune capacitors that are switched into the circuit. Once the maximum number of fine tune capacitors is switched into circuit, a coarse tune capacitor is switched in, and the fine tune capacitors are switched out. The process starts over with increasing the number of fine tune capacitors that are switched into circuit, until all fine and coarse tune capacitors are switched in, at which point another coarse tune capacitor is switched in and the fine tune capacitors are switched out. This process can continue until all the coarse and fine capacitors are switched in.

In this embodiment, all of the fine tune capacitors have the same or a substantially similar value, and all the coarse tune capacitors have the same or a substantially similar value. Further, the capacitance value of one coarse tune capacitor about equals the combined capacitance value of all fine tune capacitors plus an additional fine tune capacitor into the circuit, thus enabling a linear increase in capacitance. The embodiments, however, are not so limited. The fine tune capacitors (and coarse capacitors) need not have the same or a substantially similar value. Further, the capacitance value of one coarse tune capacitor need not equal the combined capacitance value of all fine tune capacitors plus an additional fine tune capacitor. In one embodiment, the coarse capacitance value and the fine capacitance value have a ratio substantially similar to 10:1. In another embodiment, the second capacitance value is less than or equal to one-half (½) of the first capacitance value. In another embodiment, the second capacitance value is less than or equal to one-third (⅓) of the first capacitance value. In yet another embodiment, the second capacitance value is less than or equal to one-fourth (¼) of the first capacitance value.

An example of the aforementioned embodiment in an ideal setting would be if the fine tune capacitors were equal to 1 pF, and the coarse tune capacitors were equal to 10 pF. In this ideal setup, when all switches are open, the capacitance is equal to 0 pF. When the first switch is closed, there is 1 pF in the circuit. When the second switch is closed there is 2 pF in the circuit, and so on, until nine fine tune switches are closed, giving 9 pF. Then, the first 10 pF capacitor is switched into circuit and the nine fine tune switches are opened, giving a total capacitance of 10 pF. The fine tune capacitors are then switched into circuit from 11 pF to 19 pF. Another coarse tune capacitor can then be switched into circuit and all fine tune capacitors can be switched out of circuit giving 20 pF. This process can be repeated until the desired capacitance is reached.

This can also be taken one step further. Using the previous example, having nine 1 pF capacitors and also nine 10 pF capacitors, the variable capacitor circuit can have even larger values, 100 pF, to switch in and out of circuit. This would allow the previous capacitor array to go up to 99 pF, and then the 100 pF capacitor can be used for the next increment. This can be repeated further using larger increments, and can also be used with any counting system. According to the accumulative setup, increasing the total capacitance of a variable capacitor is achieved by switching in more of the coarse capacitors or more of the fine capacitors than are already switched in without switching out a coarse capacitor that is already switched in. Further, when the variable total capacitance is increased and the control circuit does not switch in more of the coarse capacitors than are already switched in, then the control circuit switches in more fine capacitors than are already switched in without switching out a fine capacitor that is already switched in.

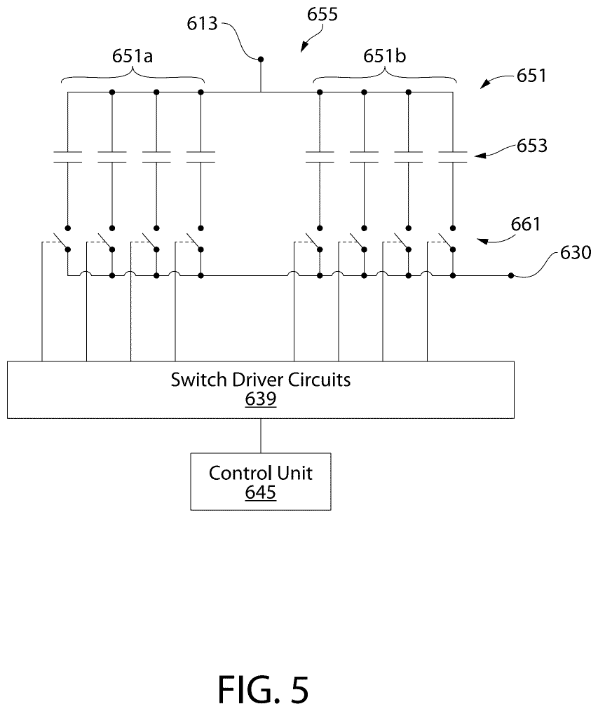

FIG. 5 is a schematic of a variable capacitance system 655 according to an accumulative setup. Where this figure uses reference numbers identical to those of FIG. 4, it is understood that the relevant components can have features similar to those discussed in FIG. 4. The variable capacitance system 655 comprises a variable capacitor 651 for providing a varying capacitance. The variable capacitor 651 has an input 613 and an output 630. The variable capacitor 651 includes a plurality of discrete capacitors 653 operably coupled in parallel. The plurality of capacitors 653 includes first (fine) capacitors 651a and second (coarse) capacitors 651B. Further, the variable capacitor 651 includes a plurality of switches 661. Of the switches 661, one switch is operably coupled in series to each of the plurality of capacitors to switch in and out each capacitor, thereby enabling the variable capacitor 651 to provide varying total capacitances. The variable capacitor 651 has a variable total capacitance that is increased when discrete capacitors 653 are switched in and decreased when the discrete capacitors 653 are switched out.

The switches 661 can be coupled to switch driver circuits 639 for driving the switches on and off. The variable capacitance system 655 can further include a control unit 645 operably coupled to the variable capacitor 651. Specifically, the control unit 645 can be operably coupled to the driver circuits 639 for instructing the driver circuits 639 to switch one or more of the switches 661, and thereby turn one or more of the capacitors 653 on or off. In one embodiment, the control unit 645 can form part of a control unit that controls a variable capacitor, such as a control unit that instructs the variable capacitors of a matching network to change capacitances to achieve an impedance match. The driver circuits 639 and control unit 645 can have features similar to those discussed above with reference to FIG. 4, and thus can also utilize an RF choke and filter as discussed above.

In one embodiment, the control circuit 645 is configured to determine a desired coarse capacitance for the coarse capacitors; determine a desired fine capacitance for the fine capacitors; and after calculating the desired coarse capacitance and the desired fine capacitance, alter the total variable capacitance by switching in or out at least one of the fine capacitors; and switching in or out at least one of the coarse capacitors. In other embodiments, coarse tuning and fine tuning can occur at different stages.

In the exemplified embodiment, the first capacitors 651a are fine capacitors each having a capacitance value substantially similar to a fine capacitance value, and the second capacitors 651b are coarse capacitors each having a capacitance value substantially similar to a coarse capacitance value, the coarse capacitance value being greater than the fine capacitance value. For purposes of this application, capacitances and other values are considered to be substantially similar if one value is not 15 percent (15%) greater than or less than another value.

The variable capacitance system 655 can form part of an impedance matching network, including but not limited to, the impedance matching networks of FIGS. 1-3. The variable capacitance system can also form part of a method for controlling an impedance matching network (such as the impedance matching networks of FIGS. 1-3). The method can include providing the matching network comprising determining an increased total capacitance to be provided by one of the EVCs; and increasing the variable total capacitance of the one EVC by switching in more of the coarse capacitors or more of the fine capacitors than are already switched in without switching out a coarse capacitor that is already switched in. Further, the variable capacitance system can form part of a method and system for fabricating a semiconductor (see FIGS. 1-3).

Using the variable capacitance system discussed above with an impedance matching network can provide several advantages over other approaches. An alternative to the above approach would be to have all the capacitor values be different, with the first value equal to the minimum desired change in capacitance. Then each successive capacitor value is increased to double the change in capacitance from the previous up until the maximum desired capacitor value, when all capacitors are switched in. This approach can result in using less capacitors to switch in and out of circuit to achieve the same resolution and range. A potential problem with this setup, however, is that, once the capacitor reaches a certain value, the voltage and/or current on that particular capacitor or the current on the switch can be higher than the specification allows for. This forces the EVC to use multiple capacitors in parallel for each switch of lower value. This problem is particularly acute where high voltages and/or currents are being used. The accumulative setup discussed above avoids putting this degree of stress on its capacitors and switches by switching in additional capacitors, rather than replacing lower-capacitance capacitors with higher-capacitance capacitors.

### Determining Capacitance Values to Achieve Match

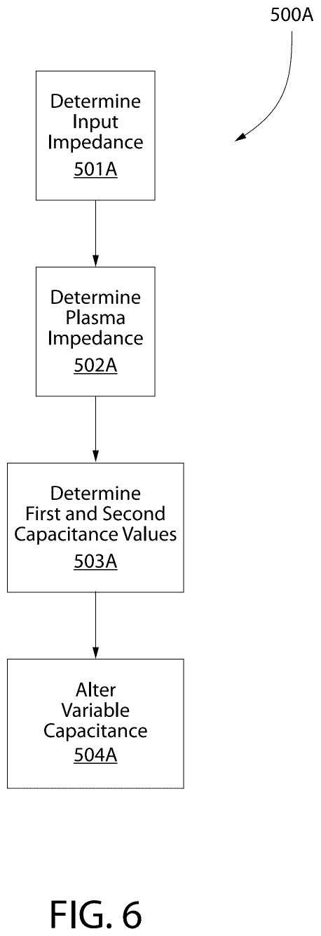

FIG. 6 is a flow chart showing a process 500A for matching an impedance according to one embodiment. The matching network can include components similar to those discussed above. In one embodiment, the matching network of FIG. 2 is utilized. In the first step of the exemplified process 500A of FIG. 6, an input impedance at the RF input 13 is determined (step 501A). The input impedance is based on the RF input parameter detected by the RF input sensor 21 at the RF input 13. The RF input sensor 21 can be any sensor configured to detect an RF input parameter at the RF input 13. The input parameter can be any parameter measurable at the RF input 13, including a voltage, a current, or a phase at the RF input 13. In the exemplified embodiment, the RF input sensor 21 detects the voltage, current, and phase at the RF input 13 of the matching network 11. Based on the RF input parameter detected by the RF input sensor 21, the control circuit 45 determines the input impedance.

Next, the control circuit 45 determines the plasma impedance presented by the plasma chamber 19 (step 502A). In one embodiment, the plasma impedance determination is based on the input impedance (determined in step 501A), the capacitance of the series EVC 31, and the capacitance of the shunt EVC 33. In other embodiments, the plasma impedance determination can be made using the output sensor 49 operably coupled to the RF output, the RF output sensor 49 configured to detect an RF output parameter. The RF output parameter can be any parameter measurable at the RF output 17, including a voltage, a current, or a phase at the RF output 17. The RF output sensor 49 may detect the output parameter at the RF output 17 of the matching network 11. Based on the RF output parameter detected by the RF output sensor 21, the control circuit 45 may determine the plasma impedance. In yet other embodiments, the plasma impedance determination can be based on both the RF output parameter and the RF input parameter.

Once the variable impedance of the plasma chamber 19 is known, the control circuit 45 can determine the changes to make to the variable capacitances of one or both of the series and shunt EVCs 31, 33 for purposes of achieving an impedance match. Specifically, the control circuit 45 determines a first capacitance value for the series variable capacitance and a second capacitance value for the shunt variable capacitance (step 503A). These values represent the new capacitance values for the series EVC 31 and shunt EVC 33 to enable an impedance match, or at least a substantial impedance match. In the exemplified embodiment, the determination of the first and second capacitance values is based on the variable plasma impedance (determined in step 502A) and the fixed RF source impedance.

Once the first and second capacitance values are determined, the control circuit 45 generates a control signal to alter at least one of the series variable capacitance and the shunt variable capacitance to the first capacitance value and the second capacitance value, respectively (step 504A). This is done at approximately t=−5 μsec. The control signal instructs the switching circuit to alter the variable capacitance of one or both of the series and shunt EVCs 31, 33.

This alteration of the EVCs 31, 33 takes about 9-11 usec total, as compared to about 1-2 sec of time for a matching network using VVCs. Once the switch to the different variable capacitances is complete, there is a period of latency as the additional discrete capacitors that make up the EVCs join the circuit and charge. This part of the match tune process takes about 55 usec. Finally, the RF power profile 403 is shown decreasing, at just before t=56 usec, from about 380 mV peak-to-peak to about 100 mV peak-to-peak. This decrease in the RF power profile 403 represents the decrease in the reflected power 407, and it takes place over a time period of about 10 usec, at which point the match tune process is considered complete.

The altering of the series variable capacitance and the shunt variable capacitance can comprise sending a control signal to the series driver circuit 39 and the shunt driver circuit 43 to control the series variable capacitance and the shunt variable capacitance, respectively, where the series driver circuit 39 is operatively coupled to the series EVC 31, and the shunt driver circuit 43 is operatively coupled to the shunt EVC 33. When the EVCs 31, 33 are switched to their desired capacitance values, the input impedance may match the fixed RF source impedance (e.g., 50 Ohms), thus resulting in an impedance match. If, due to fluctuations in the plasma impedance, a sufficient impedance match does not result, the process of 500A may be repeated one or more times to achieve an impedance match, or at least a substantial impedance match.

Using a matching network 11, such as that shown in FIG. 2, the input impedance can be represented as follows:

$${Z}_{in} = \frac{( {Z}_{P} + {Z}_{L} + {Z}_{series} ) {Z}_{shunt}}{{Z}_{P} + {Z}_{L} + {Z}_{series} + {Z}_{shunt}}$$

where Zᵢₙ is the input impedance, Z_{P} is the plasma impedance, ZI is the series inductor impedance, Zₛₑᵣᵢₑₛ is the series EVC impedance, and Zₛₕᵤₙₜ is the shunt EVC impedance. In the exemplified embodiment, the input impedance (Zᵢₙ) is determined using the RF input sensor 21. The EVC impedances (Zₛₑᵣᵢₑₛ and Zₛₕᵤₙₜ) are known at any given time by the control circuitry, since the control circuitry is used to command the various discrete capacitors of each of the series and shunt EVCs to turn ON or OFF. Further, the series inductor impedance (Z_{L}) is a fixed value. Thus, the system can use these values to solve for the plasma impedance (Z_{P}).

Based on this determined plasma impedance (Z_{P}) and the known desired input impedance

$$( {Z}_{in}^{′} )$$

(which is typically 50 Ohms), and the known series inductor impedance (Z_{L}), the system can determine a new series EVC impedance (Zₛₑᵣᵢₑₛ′) and shunt EVC impedance

$$( {Z}_{shunt}^{′} ) .$$

Based on the newly calculated series EVC variable impedance

$${Z}_{in}^{′} = \frac{( {Z}_{P} + {Z}_{L} + {Z}_{series}^{′} ) {Z}_{shunt}^{′}}{{Z}_{P} + {Z}_{L} + {Z}_{series}^{′} + {Z}_{shunt}^{′}}$$

and shunt EVC variable impedance

$$( {Z}_{series}^{′} )$$

and shunt EVC variable impendance

$$( {Z}_{shunt}^{′} ) ,$$

the system can then determine the new capacitance value (first capacitance value) for the series variable capacitance and a new capacitance value (second capacitance value) for the shunt variable capacitance. When these new capacitance values are used with the series EVC 31 and the shunt EVC 33, respectively, an impedance match may be accomplished. The exemplified method of computing the desired first and second capacitance values and reaching those values in one step is significantly faster than moving the two EVCs step-by-step to bring either the error signals to zero, or to bring the reflected power/reflection coefficient to a minimum. In semiconductor plasma processing, where a faster tuning scheme is desired, this approach provides a significant improvement in matching network tune speed.

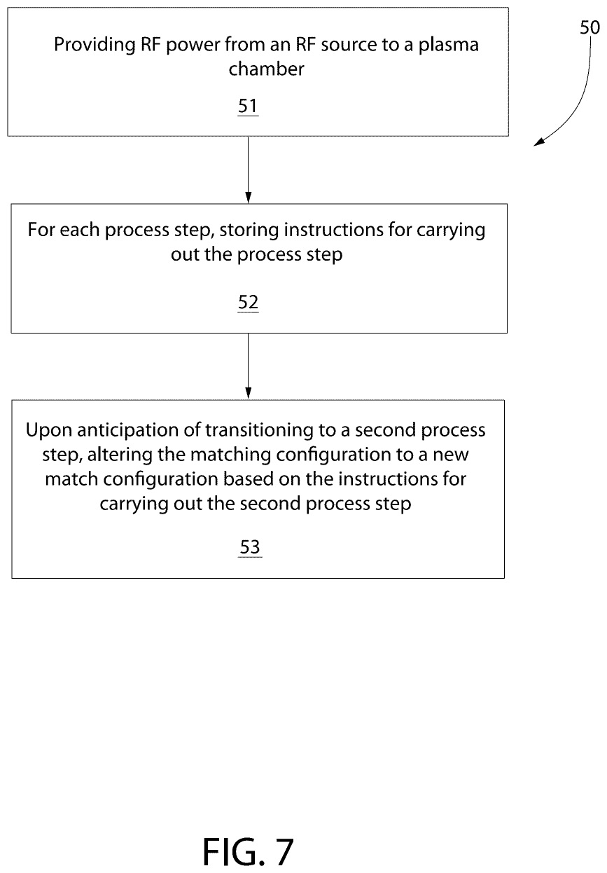

It is noted that the invention is not limited to the above process for matching an impedance. For example, the process could use a parameter matrix, as discussed in detail with respect to FIG. 7 of U.S. Pub. No. 2024/0177970, which is incorporated by reference herein in its entirety.

Those of skill in the art will recognize that several factors may contribute to the sub-millisecond elapsed time of the impedance matching process for a matching network using EVCs. Such factors may include the power of the RF signal, the configuration and design of the EVCs, the type of matching network being used, and the type and configuration of the driver circuit being used. Other factors not listed may also contribute to the overall elapsed time of the impedance matching process. Thus, it is expected that the entire match tune process for a matching network having EVCs should take no more than about 500 usec to complete from the beginning of the process (i.e., measuring by the control circuit and calculating adjustments needed to create the impedance match) to the end of the process (the point in time when the efficiency of RF power coupled into the plasma chamber is increased due to an impedance match and a reduction of the reflected power). Even at a match tune process on the order of 500 usec, this process time still represents a significant improvement over matching networks using VVCs.

Table 1 presents data showing a comparison between operational parameters of one example of an EVC versus one example of a VVC. As can be seen, EVCs present several advantages, in addition to enabling fast switching for a matching network:

TABLE 1

| | | | Typical 1000 pF | |
|---|---|---|---|---|
| Parameter | EVC | | Vacuum Capacitors | |
| Capacitance | 20 pF~1400 pF | | 15 pF~1000 pF | |
| Reliability | High | | Low | |
| Response Time | ~500 | μsec | 1 s~2 s | |
| ESR | ~13 | mW | ~20 | mW |
| Voltage | 7 | kV | 5 | kV |
| Current Handling Capability | 216 | A rms | 80 | A rms |
| Volume | 4.5 | in³ | 75 | in³ |

As is seen, in addition to the fast switching capabilities made possible by the EVC, EVCs also introduce a reliability advantage, a current handling advantage, and a size advantage. Additional advantages of the matching network using EVCs and/or the switching circuit itself for the EVCs include:
The disclosed matching network does not include any moving parts, so the likelihood of a mechanical failure reduced to that of other entirely electrical circuits which may be used as part of the semiconductor fabrication process. For example, the typical EVC may be formed from a rugged ceramic substrate with copper metallization to form the discrete capacitors. The elimination of moving parts also increases the resistance to breakdown due to thermal fluctuations during use.
The EVC has a compact size as compared to a VVC, so that the reduced weight and volume may save valuable space within a fabrication facility.
The design of the EVC introduces an increased ability to customize the matching network for specific design needs of a particular application. EVCs may be configured with custom capacitance ranges, one example of which is a non-linear capacitance range. Such custom capacitance ranges can provide better impedance matching for a wider range of processes. As another example, a custom capacitance range may provide more resolution in certain areas of impedance matching. A custom capacitance range may also enable generation of higher ignition voltages for easier plasma strikes.
The short match tune process (˜500 usec or less) allows the matching network to better keep up with plasma changes within the fabrication process, thereby increasing plasma stability and resulting in more controlled power to the fabrication process.
The use of EVCs, which are digitally controlled, non-mechanical devices, in a matching network provides greater opportunity to fine tune control algorithms through programming.
EVCs exhibit superior low frequency (kHz) performance as compared to VVCs.

### Controlling a Matching Network to Adjust Configurations Between Process Steps

FIG. 7 is a flow chart for a method 50 of controlling a matching network of a semiconductor manufacturing system, the method 50 enabling the matching network to change match configurations in anticipation of a new process step. The method will be described with respect to the embodiments provided in FIGS. 1-6 and its system 87 for controlling matching network 11, the system including the matching network 11, a control circuit 45, and a memory 46, though the invention is not so limited. It is noted that the control circuit and/or memory may form part of the matching network (FIG. 2) or be separate therefrom (FIG. 1).

In a first operation 51, a matching network 11 provides RF power from an RF source 15 to a plasma chamber 19. The matching network comprises an electronically variable reactance element (EVRE) configured to provide a variable total reactance. In this example, the EVRE is an electronically variable capacitor (EVC) 31, 33, though the invention is not so limited. Generally, an EVRE may include one or more discrete reactance elements, where a reactance element is a capacitor or inductor or similar reactive device. In this embodiment, referring to FIG. 5, the EVC 651 (which may be used for EVCs 31, 33) comprises discrete capacitors 653 configured to switch in and out of the matching network 11 to vary the total capacitance provided by the EVC 651 and thereby enable the matching network 11 to provide different match configurations. The alteration of the match configuration causes the RF power reflected back to the RF source 15 to decrease.

In the exemplified embodiment, the matching network 11 includes two EVCs 31, 33, though the invention is not limited to a particular number of EVCs or EVREs. In embodiments with more than one EVRE, each of the EVREs has different positions depending on which of the discrete reactance elements are switched in and out. The different match configurations of the matching network are the different combinations of the match positions for the EVREs. Thus, if a matching network has two EVREs, the match configuration for that matching network at any given time will be the combination of the match position of the first EVRE and the match position of the second EVRE. If a matching network had one EVRE, the matching configuration for that matching network at any given time may be simply the match position of the singe EVRE.

The plasma chamber 19 is configured to carry out a process upon a substrate 27, the process comprising process steps including at least a first process step and a second process step. As discussed above, the plasma chamber 19 may, for example, deposit a material layer on the substrate 27 or etch a material layer from the substrate 27. A process step may be a deposition step, an etch step, a diffusion step, another treatment step, or any other type of step in a process carried out by the plasma chamber.

In a second operation 52, for each process step, a memory 46 stores instructions for carrying out the process step. These instructions may include different parameters or recipes for the relevant process. For example, the instructions for a given step may comprise instructions for a power level for the RF power of the RF source 15. The instructions may also comprise instructions indicating the type of power to be provided, such as a continuous wave signal or a pulsing RF signal.

In a third operation 53, while continuously carrying out each of the process steps of the process, upon anticipation that the plasma chamber will be transitioning from the first process step to the second process step, the control circuit alters the match configuration to a new match configuration based on the instructions for carrying out the second process step. For example, different steps may require different power levels being provided by the RF source 15. One process step may have a high power (e.g., 1000 W), and another process may run a lower power level (e.g., 300 W). The transition from one power to another may be very rapid. If the power shuts off between process steps, the time of the power being off may be very short (e.g., tens of milliseconds). As discussed below, with the speed of switching an EVC or other EVRE, the transition between steps provides an opportunity to alter the match configuration to one more suitable for the new process about to begin. The control circuit may anticipate the transition in process steps in a variety of ways. For example, the control circuit may store or be provided data indicative of the timing of the transition.

A continuous carrying out each of the process steps may be understood to be a process that continues with its process steps until achieving a predetermined result upon the substrate. The result may comprise, for example, a desired thickness, a desired uniformity of coverage, a desired etch upon the substrate, or a desired material property of the film or other material layer. A continuous carrying out each of the process steps may also be understood as carrying out a series of process steps while the plasma chamber remains ignited. A continuous carrying out each of the process steps may also be understood as a series of process steps where the RF power does not shut off for more than a certain period of time, such as 500 microseconds or 100 microseconds. It is noted that the alteration of the match configuration may occur prior to the plasma chamber beginning the second process step, and may occur during the brief time between the first process step and the second process step.

In addition to (or instead of) altering the match configuration upon anticipation that the plasma chamber will be transitioning process steps, the control circuit may be configured to alter a tuning parameter of the matching network to a new tuning parameter, the new tuning parameter being based on the instructions for carrying out the new (e.g., second) process step. The tuning parameter may be, for example, a predetermined condition for when impedance matching starts. For example, impedance matching may start when a predetermined amount of reflected power (or a related parameter indicative or reflected power, such as a reflection coefficient) is exceeded, or output power or a related parameter at the output of the matching network drops below a certain level. The tuning parameter may also be a predetermined condition for when impedance matching ends. For example, impedance matching may end when there is less than a predetermined amount of reflected power or a related parameter, or output power or a related parameter increases above a certain level. The tuning parameter may also be a predetermined condition for when impedance matching should restart after having stopped. For example, impedance matching may restart when exceeding a predetermined amount of reflected power or a related parameter, or dropping below certain output power or a related parameter for more than a certain number of control loops (e.g., 2 control loops) or for more than a certain amount of time.

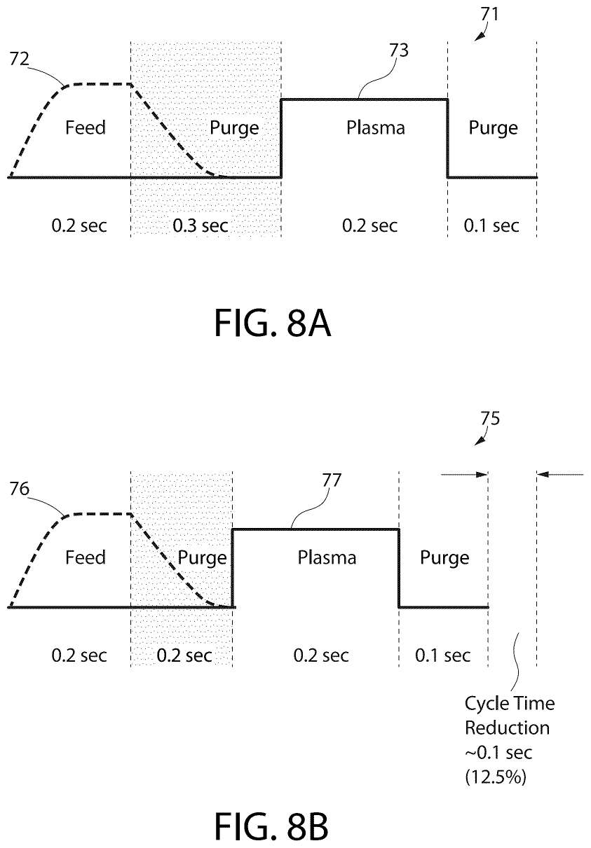

FIGS. 8A-B provide graphs 71, 75 comparing the speed of a Plasma Enhanced Atomic Layer Deposition (PEALD) semiconductor process with and without the disclosed system for controlling a matching network of the semiconductor processing system. FIG. 8A's graph 71 illustrates a PEALD process not using the disclosed method of adjusting the matching configuration in anticipation of a new process step. Waveform 72 represents the gas supplied to the plasma chamber, and waveform 73 represents the RF power being supplied to the plasma chamber. These parameters are shown over the course of feed, purge, plasma, and purge stages. The total cycle time is 0.8 seconds.

FIG. 8B's graph 75 illustrates a PEALD process using the disclosed method of adjusting the matching configuration in anticipation of a new process step. Waveform 76 represents the gas supplied to the plasma chamber, and waveform 77 represents the RF power being supplied to the plasma chamber. These parameters are shown over the course of the same feed, purge, plasma, and purge stages as the first graph 71. As may be observed, the total cycle time is 0.7 seconds, and thus 0.1 seconds faster than the process not using the disclosed method. For the reasons discussed above, this reduced cycle time is to be expected since the rapid change of the match configuration in anticipation of the new process step enables faster impedance matching when transition process steps, thus enabling power to be supplied to the plasma chamber effectively at the time of a process change.

While the embodiments of a matching network discussed herein have used L or pi configurations, it is noted that he claimed matching network may be configured in other matching network configurations, such as a ‘T’ type configuration. Unless stated otherwise, the variable capacitors, switching circuits, and methods discussed herein may be used with any configuration appropriate for a matching network.

While the embodiments discussed herein use one or more variable capacitors in a matching network to achieve an impedance match, it is noted that any variable reactance element can be used. A variable reactance element can include one or more discrete reactance elements, where a reactance element is a capacitor or inductor or similar reactive device.

While the inventions have been described with respect to specific examples including presently preferred modes of carrying out the invention, those skilled in the art will appreciate that there are numerous variations and permutations of the above described systems and techniques. It is to be understood that other embodiments may be utilized and structural and functional modifications may be made without departing from the scope of the present inventions. Thus, the spirit and scope of the inventions should be construed broadly as set forth in the appended claims.

What is claimed is:

1. A system for controlling a matching network of a semiconductor manufacturing system, the system comprising:
a matching network configured to provide a radio frequency (RF) power from an RF source to a plasma chamber;
wherein the matching network comprises an electronically variable reactance element (EVRE) configured to provide a variable total reactance, the EVRE comprising discrete reactance elements configured to switch in and out of the matching network to vary the total reactance provided by the EVRE and thereby enable the matching network to provide different match configurations;
wherein the plasma chamber is configured to carry out a process upon a substrate, the process comprising process steps including at least a first process step and a second process step;
a memory configured, for each process step, to store instructions for carrying out the process step; and
a control circuit configured to, while continuously carrying out each of the process steps of the process, upon anticipation that the plasma chamber will be transitioning from the first process step to the second process step, alter the match configuration to a new match configuration based on the instructions for carrying out the second process step.

2. The system of claim 1, wherein the continuous carrying out of the process steps achieves a predetermined result upon the substrate, the predetermined result comprising a desired thickness, a desired uniformity of coverage, a desired etch upon the substrate, or a desired material property of a film.

3. The system of claim 1, wherein, during the continuous carrying out of the process steps, a plasma of the plasma chamber remains ignited.

4. The system of claim 1, wherein, during the continuous carrying out of the process steps, the RF power does not shut off for more than 500 microseconds.

5. The system of claim 1, wherein the alteration of the match configuration occurs prior to the plasma chamber transitioning to the second process step.

6. The system of claim 1, wherein the control circuit is further configured to, while continuously carrying out each of the process steps of the process, upon the anticipation that the plasma chamber will be transitioning from the first process step to the second process step, alter a tuning parameter of the matching network to a new tuning parameter, the new tuning parameter being based on the instructions for carrying out the second process step.

7. The system of claim 6, wherein the tuning parameter is at least one of:
a predetermined condition for when impedance matching starts;
a predetermined condition for when impedance matching ends; or
a predetermined condition for when impedance matching should restart after having stopped.

8. The system of claim 1, wherein the process steps include at least one of a deposition process, a removal process, or a treatment process.

9. The system of claim 1, wherein the instructions for carrying out the first step and the instructions for carrying out the second step comprise instructions for different power levels for the RF power of the RF source.

10. The system of claim 1, wherein the instructions for carrying out the first step comprise instructions for the RF power to be provided by a pulsing RF signal, and the instructions for carrying out the second step comprise instructions for the RF power to be provided by a continuous wave signal.

11. The system of claim 1, wherein the alteration of the matching network to the new match configuration cause RF power reflected back to the RF source to decrease.

12. The system of claim 1:
wherein the matching network further comprises a second EVRE comprising discrete reactance elements configured to switch in and out of the matching network to vary the total reactance provided by the second EVRE;
wherein each of the EVREs has different positions depending on which of the discrete reactance elements are switched in and out of the matching network; and
wherein different match configurations of the matching network comprise the different combinations of the match positions for the EVREs.

13. A method of controlling a matching network of a semiconductor manufacturing system, the method comprising:
providing, by a matching network, RF power from an RF source to a plasma chamber;
wherein the matching network comprises an electronically variable reactance element (EVRE) configured to provide a variable total reactance, the EVRE comprising discrete reactance elements configured to switch in and out of the matching network to vary the total reactance provided by the EVRE and thereby enable the matching network to provide different match configurations;
wherein the plasma chamber is configured to carry out a process upon a substrate, the process comprising process steps including at least a first process step and a second process step;
for each process step, storing instructions for carrying out the process step; and
while continuously carrying out each of the process steps of the process, upon anticipation that the plasma chamber will be transitioning from the first process step to the second process step, altering the match configuration to a new match configuration based on the instructions for carrying out the second process step.

14. The method of claim 13, wherein the continuous carrying out of the process steps achieves a predetermined result upon the substrate, the predetermined result comprising a desired thickness, a desired uniformity of coverage, or a desired material property of a film.

15. The method of claim 13, wherein, during the continuous carrying out of the process steps, a plasma of the plasma chamber remains ignited.

16. The method of claim 13, wherein, during the continuous carrying out of the process steps, the RF power does not shut off for more than 100 microseconds.

17. The method of claim 13, wherein the alteration of the match configuration occurs prior to the plasma chamber transitioning to the second process step.

18. The method of claim 13, further comprising, while continuously carrying out each of the process steps of the process, upon the anticipation that the plasma chamber will be transitioning from the first process step to the second process step, altering a tuning parameter of the matching network to a new tuning parameter, the new tuning parameter being based on the instructions for carrying out the second process step.

19. The method of claim 18, wherein the tuning parameter is at least one of:
a predetermined condition for when impedance matching starts;
a predetermined condition for when impedance matching ends; or
a predetermined condition for when impedance matching should restart after having stopped.

20. The method of claim 13, wherein the process steps include at least one of a deposition process, a removal process, or a treatment process.
